(19) United States
(12) Patent Application Publication
(10) Pub. No.: US 2017/0084480 A1
(43) Pub. Date: Mar. 23, 2017

(54) SUBSTRATE PROCESSING APPARATUS, SUBSTRATE PROCESSING METHOD AND RECORDING MEDIUM

(71) Applicant: Tokyo Electron Limited, Tokyo (JP)

(72) Inventors: Nobutaka Mizutani, Nirasaki City (JP); Mitsuaki Iwashita, Nirasaki City (JP); Takashi Tanaka, Nirasaki City (JP)

(21) Appl. No.: 15/264,661

(22) Filed: Sep. 14, 2016

(30) Foreign Application Priority Data
Sep. 18, 2015 (JP) 2015-185751

(51) Int. Cl. H01L 21/768; H01L 23/532; H01L 21/67; H01L 23/522; H01J 37/32; C23C 18/16

(52) U.S. Cl. CPC H01L 21/76814; H01J 37/32009; C23C 18/1633; H01J 37/3244; H01L 21/67051; H01L 21/76843; H01L 21/76879; H01L 23/5226; H01L 23/53238; H01J 2237/334

(57) ABSTRACT

A substrate processing apparatus can remove, from a substrate having a copper wiring formed by a dry etching process using an organic etching gas, e.g., one or more kinds of organic etching gases selected from a methane gas, a CF-based gas, a carboxylic acid-based gas containing a methyl group and an alcohol-based gas, an organic polymer which is originated from the organic etching gas and generated in the dry etching process and adheres to a surface of the substrate. In a substrate processing apparatus 1, a first processing unit 4 includes a first cleaning liquid supply unit 43a configured to supply a first cleaning liquid L1 selected from a chemical liquid containing hydrogen peroxide and a chemical liquid containing a polar organic solvent, and the first cleaning liquid L1 is supplied onto a substrate W1 from the first cleaning liquid supply unit 43a.

### CROSS-REFERENCE TO RELATED APPLICATION

This application claims the benefit of Japanese Patent Application No. 2015-185751 filed on Sep. 18, 2015, the entire disclosures of which are incorporated herein by reference.

### TECHNICAL FIELD

The embodiments described herein pertain generally to a substrate processing apparatus and a substrate processing method. Further, the embodiments are also related to a recording medium having stored thereon a program for implementing the substrate processing method.

### BACKGROUND

Recently, an operating speed of a semiconductor device, particularly, a semiconductor integrated circuit device is getting higher. A high operating speed is achieved by reducing resistance of a wiring material, or the like. For this purpose, copper having lower resistance is widely utilized as the wiring material instead of conventionally used aluminum.

Patent Document 1 describes an anisotropic dry etching method of copper as a method of forming a copper wiring.

Patent Document 1: Japanese Patent Laid-open Publication No. 2012-054306

The present inventors have found out that if a copper wiring is formed on a substrate by a dry etching process using an organic etching gas, e.g., one or more kinds of organic etching gases selected from a methane gas, a CF-based gas, a carboxylic acid-based gas containing a methyl group, and an alcohol-based gas, an organic polymer originated from the organic etching gas and generated in the dry etching process is attached to a surface of the substrate on which the dry etching process is performed.

This organic polymer may be an obstacle to forming a metal film on the copper wiring of the substrate by performing an electroless plating process or the like.

### SUMMARY

In view of the foregoing, exemplary embodiments provide a substrate processing apparatus and a substrate processing method capable of removing, from a substrate having a copper wiring formed by a dry etching process, an organic polymer which is originated from an etching gas and generated in the dry etching process and adheres to a surface of the substrate. Further, the exemplary embodiments also provide a recording medium having stored thereon a program for implementing this substrate processing method.

The present inventors have found out that by cleaning a substrate having a copper wiring, which is formed by a dry etching process using an organic etching gas, e.g., one or more kinds of organic etching gases selected from a methane gas, a CF-based gas, a carboxylic acid-based gas containing a methyl group and an alcohol-based gas, with a cleaning liquid selected from a chemical liquid containing hydrogen peroxide and a chemical liquid containing a polar organic solvent, an organic polymer which is originated from the organic etching gas and generated in the dry etching process and adheres to a surface of the substrate can be removed. Further, the present inventors have also found out that by performing a cleaning process using a cleaning liquid selected from an aqueous solution containing hydrogen fluoride and a strong alkaline aqueous solution after performing a cleaning process using the cleaning liquid selected from the chemical liquid containing the hydrogen peroxide and the chemical liquid containing the polar organic solvent, the effect of removing the organic polymer is further improved. Based on these observations, the present inventors have reached the present disclosure. Furthermore, the present inventors have actually observed through a microscope that the organic polymer is removed by the cleaning processes using the aforementioned cleaning liquids.

The present disclosure includes following exemplary embodiments.

(1) A substrate processing apparatus including a cleaning processing unit configured to perform a cleaning process of removing, from a substrate having a copper wiring formed by a dry etching process using an organic etching gas, an organic polymer which is originated from the organic etching gas and generated in the dry etching process and adheres to a surface of the substrate; and a control unit configured to control an operation of the cleaning processing unit,

wherein the cleaning processing unit comprises a first cleaning liquid supply unit configured to supply a first cleaning liquid selected from a chemical liquid containing hydrogen peroxide and a chemical liquid containing a polar organic solvent onto the substrate, and

the control unit controls the first cleaning liquid supply unit such that the first cleaning liquid is supplied onto the substrate by the first cleaning liquid supply unit.

(2) The substrate processing apparatus as described in (1),

wherein the organic etching gas is one or more kinds of gases selected from a methane gas, a CF-based gas, a carboxylic acid-based gas containing a methyl group and an alcohol-based gas.

(3) The substrate processing apparatus as described in (1) or (2),

wherein the cleaning processing unit further comprises a second cleaning liquid supply unit configured to supply a second cleaning liquid, which is selected from an aqueous solution containing hydrogen fluoride and a strong alkaline aqueous solution, onto the substrate, and

the control unit controls the first cleaning liquid supply unit and the second cleaning liquid supply unit such that the second cleaning liquid is supplied onto the substrate by the second cleaning liquid supply unit after the first cleaning liquid is supplied by the first cleaning liquid supply unit.

(4) The substrate processing apparatus as described in (3),

wherein the cleaning processing unit further comprises a third cleaning liquid supply unit configured to supply a third cleaning liquid which is selected from an aqueous solution containing hydrogen fluoride and a strong alkaline aqueous solution and is different from the second cleaning liquid, and

the control unit controls the first cleaning liquid supply unit, the second cleaning liquid supply unit and the third cleaning liquid supply unit such that the third cleaning liquid is supplied onto the substrate by the third cleaning liquid supply unit after the second cleaning liquid is supplied by the second cleaning liquid supply unit.

(5) The substrate processing apparatus as described in (3) or (4), wherein the cleaning processing unit further comprises a rinse liquid supply unit configured to supply a rinse liquid onto the substrate, and

the control unit controls the first cleaning liquid supply unit, the second cleaning liquid supply unit, the third cleaning liquid supply unit and the rinse liquid supply unit such that the rinse liquid is supplied onto the substrate from the rinse liquid supply unit after the first cleaning liquid is supplied by the first cleaning liquid supply unit and before the second cleaning liquid is supplied by the second cleaning liquid supply unit, and/or after the second cleaning liquid is supplied by the second cleaning liquid supply unit and before the third cleaning liquid is supplied by the third cleaning liquid supply unit.

(6) The substrate processing apparatus as described in any one of (1) to (5), further comprising:

a coating processing unit configured to perform a coating process of coating the copper wiring of the substrate with a metal film,

wherein the control unit controls the cleaning processing unit and the coating processing unit such that the coating process is performed on the substrate by the coating processing unit after performing the cleaning process by the cleaning processing unit.

(7) The substrate processing apparatus as described in (6), further comprising:

a hydrophobizing agent solution supply unit configured to supply a hydrophobizing agent solution onto the substrate,

wherein the control unit controls the cleaning processing unit, the coating processing unit and the hydrophobizing agent solution supply unit such that the hydrophobizing agent solution is supplied onto the substrate by the hydrophobizing agent solution supply unit after performing the cleaning process by the cleaning processing unit and before performing the coating process by the coating processing unit.

(8) The substrate processing apparatus as described in (6) or (7),

wherein the coating process is an electroless plating process.

(9) A substrate processing method including a cleaning process of removing, from a substrate having a copper wiring formed by a dry etching process using an organic etching gas, an organic polymer which is originated from the organic etching gas and generated in the dry etching process and adheres to a surface of the substrate,

wherein, in the cleaning process, a first cleaning liquid selected from a chemical liquid containing hydrogen peroxide and a chemical liquid containing a polar organic solvent is supplied onto the substrate.

(10) The substrate processing method as described in (9),

wherein the organic etching gas is one or more kinds of gases selected from a methane gas, a CF-based gas, a carboxylic acid-based gas containing a methyl group and an alcohol-based gas.

(11) The substrate processing method as described in (9) or (10),

wherein, in the cleaning process, a second cleaning liquid selected from an aqueous solution containing hydrogen fluoride and a strong alkaline aqueous solution is supplied onto the substrate after the first cleaning liquid is supplied.

(12) The substrate processing method as described in (11),

wherein, in the cleaning process, a third cleaning liquid, which is selected from an aqueous solution containing hydrogen fluoride and a strong alkaline aqueous solution and is different from the second cleaning liquid, is supplied onto the substrate after the second cleaning liquid is supplied.

(13) The substrate processing method as described in (11) or (12),

wherein, in the cleaning process, a rinse liquid is supplied onto the substrate after the first cleaning liquid is supplied and before the second cleaning liquid is supplied, and/or after the second cleaning liquid is supplied and before the third cleaning liquid is supplied.

(14) The substrate processing method as described in any one of (9) to (13), further comprising:

a coating process of coating the copper wiring of the substrate with a metal film after the cleaning process.

(15) The substrate processing method as described in (14), further comprising:

a hydrophobizing agent solution supplying process of supplying a hydrophobizing agent solution onto the substrate after the cleaning process and before the coating process.

(16) The substrate processing method as described in (14) or (15),

wherein, in the coating process, the copper wiring of the substrate is coated with the metal film by an electroless plating process.

(17) A substrate processing method, comprising:

preparing a substrate having a copper wiring provided with a preset wiring pattern by a dry etching process;

removing an organic polymer, which is originated from an etching gas and generated in the dry etching process and adheres to a surface of the copper wiring, with a cleaning liquid; and

coating the surface of the copper wiring of the substrate selectively with a metal film after the removing of the organic polymer.

(18) A computer-readable recording medium having stored thereon computer-executable instructions that, in response to execution, cause a substrate processing apparatus to perform a substrate processing method as described in any one of (9) to (17).

In accordance with the exemplary embodiments, it is possible to provide a substrate processing apparatus and a substrate processing method capable of removing, from a substrate having a copper wiring formed by a dry etching process, an organic polymer which is originated from an etching gas and generated in the dry etching process and adheres to a surface of the substrate. Furthermore, according to the exemplary embodiments, it is also possible to provide a recording medium having stored thereon a program for implementing this substrate processing method.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic plan view illustrating a configuration of a substrate processing apparatus according to an exemplary embodiment;

FIG. 2 is a schematic plan view illustrating a configuration of a substrate processing unit provided in the substrate processing apparatus shown in FIG. 1;

FIG. 3 is a schematic cross sectional view illustrating a configuration of a first processing unit provided in the substrate processing unit shown in FIG. 2;

FIG. 4 is a schematic cross sectional view illustrating a configuration of a second processing unit provided in the substrate processing unit shown in FIG. 2;

FIG. 5A is a schematic cross sectional view for describing a dry etching process;

FIG. 5B is a schematic cross sectional view for describing the dry etching process (following FIG. 5A);

FIG. 5C is a schematic cross sectional view for describing the dry etching process (following FIG. 5B);

FIG. 5D is a schematic cross sectional view for describing the dry etching process (following FIG. 5C); and

FIG. 6 is a schematic cross sectional view illustrating a configuration of a modification example of the first processing unit shown in FIG. 3.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

<Configuration of Substrate Processing Apparatus>

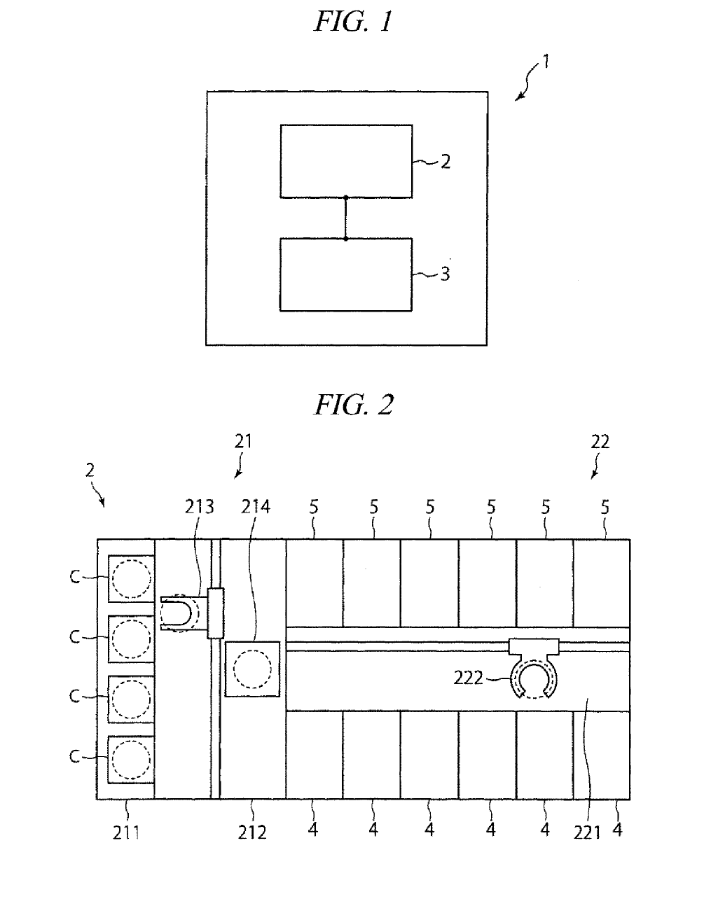

A configuration of a substrate processing apparatus according to an exemplary embodiment will be described with reference to FIG. 1. FIG. 1 is a schematic diagram illustrating the configuration of the substrate processing apparatus according to the exemplary embodiment.

As depicted in FIG. 1, a substrate processing apparatus 1 according to the exemplary embodiment includes a substrate processing unit 2; and a control unit 3 configured to control an operation of the substrate processing unit 2.

The substrate processing unit 2 is configured to perform various processings on a substrate. The various processings performed by the substrate processing unit 2 will be described later.

The control unit 3 is implemented by, for example, a computer, and includes a main control unit and a storage unit. The main control unit may be, for example, a CPU (Central Processing Unit) and controls an operation of the substrate processing unit 2 by reading and executing a program stored in the storage unit. The storage unit may be implemented by, by way of non-limiting example, a storage device such as a RAM (Random Access Memory), a ROM (Read Only Memory) or a hard disk, and is configured to store various programs for controlling the various processings performed in the substrate processing unit 2. Further, the programs may be recorded on a computer-readable recording medium, or may be installed from this recording medium to the storage unit. The computer-readable recording medium may include, by way of example, but not limitation, a hard disc (HD), a flexible disc (FD), a compact disc (CD), a magnet optical disc (MO), a memory card, and so forth. The recording medium has stored thereon programs that, when executed by the computer for controlling the operation of the substrate processing apparatus 1, cause the substrate processing apparatus 1 to perform a substrate processing method to be described later under the control of the computer.

<Configuration of Substrate Processing Unit>

Now, a configuration of the substrate processing unit 2 will be explained with reference to FIG. 2. FIG. 2 is a schematic plan view illustrating the configuration of the substrate processing unit 2, and a dotted line in FIG. 2 indicates a substrate.

The substrate processing unit 2 is configured to perform various processings on the substrate. The processings performed by the substrate processing unit 2 are not particularly limited as long as the processings include a cleaning process of removing, from a substrate having a copper wiring formed by a dry etching process using an organic etching gas, e.g., one or more kinds of organic etching gases selected from a methane gas, a CF-based gas, a carboxylic acid-based gas containing a methyl group and an alcohol-based gas, an organic polymer which is originated from the organic etching gas and generated in the dry etching process to adhere to a surface of the substrate. Thus, the processings performed by the substrate processing unit 2 may include another process other than the cleaning process of removing the organic polymer. By way of example, the processings performed by the substrate processing unit 2 may include a dry etching process using an organic etching gas, e.g., one or more kinds of organic etching gases selected from a methane gas, a CF-based gas, a carboxylic acid-based gas containing a methyl group, and an alcohol-based gas. In the present exemplary embodiment, the substrate processing unit 2 performs a processing including the cleaning process of removing the organic polymer adhering to the surface of the substrate on which the dry etching process is performed, and an electroless plating process of coating a copper wiring of the substrate, on which the cleaning process is performed, with a metal film. Furthermore, the electroless plating process is an example of a coating process of coating the copper wiring of the substrate, on which the cleaning process is performed, with a metal film.

The substrate processing unit 2 includes a carry-in/out station 21; and a processing station 22 provided adjacent to the carry-in/out station 21.

The carry-in/out station 21 includes a placing section 211; and a transfer section 212 provided adjacent to the placing section 211.

In the placing section 11, a plurality of transfer containers (hereinafter, referred to as “carriers C”) is placed to accommodate a plurality of substrates horizontally.

The transfer section 212 is provided with a transfer device 213 and a delivery unit 214. The transfer device 213 is provided with a holding mechanism configured to hold a substrate thereon. The transfer device 213 is configured to be movable horizontally and vertically and pivotable around a vertical axis.

The processing station 22 is equipped with first processing units 4 and second processing units 5. The first processing units 4 are configured to perform a processing including the cleaning process of removing, from the substrate after performing the dry etching process, the organic polymer adhering to the surface of the substrate. The second processing units 5 are configured to perform a processing including the electroless plating process of coating the copper wiring of the substrate, on which the cleaning process has been performed, with a metal film. In the present exemplary embodiment, the number of the first processing units 4 provided in the processing station 22 may be two or more, but it is also possible to provide only one first processing unit 4. Likewise, the number of the second processing units 5 may be two or more, but it is still possible to provide only one second processing unit 5. The first processing units 4 are arranged at one side of a transfer path 221 which is elongated in a preset direction, and the second processing units 5 are arranged at the other side of the transfer path 221.

The transfer path 221 is provided with a transfer device 222. The transfer device 222 includes a holding mechanism configured to hold a substrate thereon, and is configured to be movable horizontally and vertically and pivotable around a vertical axis.

Hereinafter, a substrate before performing a substrate processing by a first processing unit 4 (that is, substrate as a processing target by the first processing unit 4) will be referred to as “substrate W1”; a substrate after performing the substrate processing by the first processing unit 4 and before performing a substrate processing by the second processing unit 5 (that is, substrate as a processing target by the second processing unit 5) will be referred to as “substrate W2”; and a substrate after performing the substrate processing by the second processing unit 5 will be referred to as “substrate W3”.

In the substrate processing unit 2, the transfer device 213 of the carry-in/out station 21 is configured to transfer the substrates W1 and W3 between the carriers C and the delivery unit 214. To elaborate, the transfer device 213 takes out the substrate W1 from the carrier C placed in the placing section 211, and then, places the substrate W1 in the delivery unit 214. Further, the transfer device 213 takes out the substrate W3 which is placed in the delivery unit 214 by the transfer device 222 of the processing station 22, and then, accommodates the substrate W3 in the carrier C of the placing section 211.

In the substrate processing unit 2, the transfer device 222 of the processing station 22 is configured to transfer the substrate W1 between the delivery unit 214 and the first processing unit 4, transfer the substrate W2 between the first processing unit 4 and the second processing unit 5 and transfer the substrate W3 between the second processing unit 5 and the delivery unit 214. To elaborate, the transfer device 222 takes out the substrate W1 placed in the delivery unit 214 and carries the substrate W1 into the first processing unit 4. Further, the transfer device 222 takes out the substrate W2 from the first processing unit 4 and carries the substrate W2 into the second processing unit 5. Furthermore, the transfer device 222 takes out the substrate W3 from the second processing unit 5 and places the substrate W3 in the delivery unit 214.

<Configuration of First Processing Unit>

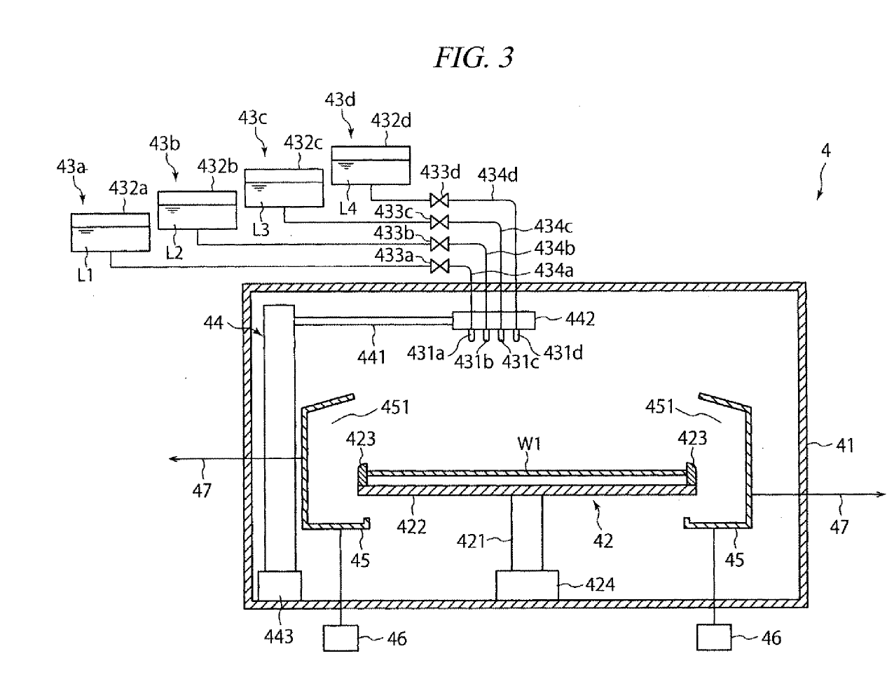

Now, a configuration of the first processing unit 4 will be explained with reference to FIG. 3. FIG. 3 is a schematic cross sectional view illustrating the configuration of the first processing unit 4.

The first processing unit 4 is configured to perform a processing including a cleaning process of removing, from the substrate W1, an organic polymer adhering to a surface of the substrate W1. The processing performed by the first processing unit 4 is not particularly limited as long as the cleaning process of removing the organic polymer adhering to the surface of the substrate W1 is included therein. That is, the processing performed by the first processing unit 4 may include another process other than the mentioned cleaning process.

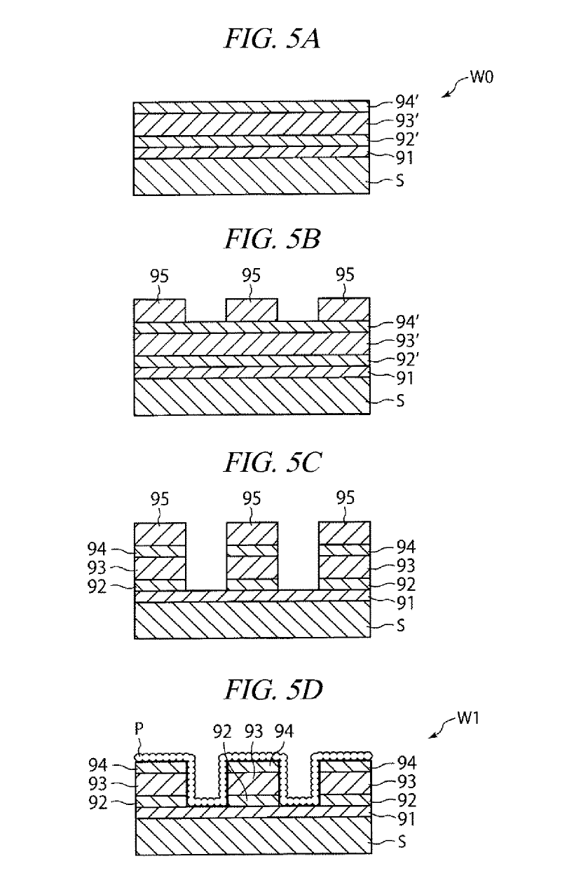

In the present exemplary embodiment, the substrate W1 is a substrate obtained after performing a dry etching process. As depicted in FIG. 5D, the substrate W1 includes a semiconductor wafer S, an interlayer insulating film 91 formed on the semiconductor wafer S, a first barrier film 92 formed on the interlayer insulating film 91, a copper wiring 93 formed on the first barrier film 92 and a second barrier film 94 formed on the copper wiring 93. Further, attached to a surface of the substrate W1 is an organic polymer P which is originated from an etching gas (an organic etching gas, e.g., one or more organic etching gases selected from a methane gas, a CF-based gas, a carboxylic acid-based gas containing a methyl group, and an alcohol-based gas) and generated in the dry etching process. In the substrate W1, the second barrier film 94 can be omitted.

The semiconductor wafer S may be, by way of non-limiting example, a silicon wafer. The interlayer insulating film 91 may be a SiO₂ film or a low dielectric constant film called a “Low-k film”. The Low-k film is a film having a relative dielectric constant lower than that of silicon dioxide, e.g., a SiOC film. The copper wiring 93 is formed by the dry etching process using the organic etching gas, e.g., one or more organic etching gases selected from the methane gas, the CF-based gas, the carboxylic acid-based gas containing the methyl group and the alcohol-based gas, and is provided with a preset wiring pattern. The first barrier film 92 is provided to suppress copper atoms in the copper wiring 93 from being diffused into the interlayer insulating film 91 and the semiconductor wafer S, and the second barrier film 94 is provided to suppress oxidation of the copper wiring 93. The first barrier film 92 and the second barrier film 94 are made of, by way of example, but not limitation, a metal such as Ti, Nb, Cr, W, Ta or MO, or a nitride or an oxide thereof. For example, each of the first barrier film 92 and the second barrier film 94 may be implemented by a stacked film of Ta/TaN or a stacked film of Ti/TiN.

The first processing unit 4 includes a chamber 41, and is configured to perform a substrate processing including the cleaning process within the chamber 41.

The first processing unit 4 is provided with a substrate holding unit 42. The substrate holding unit 42 includes a rotation shaft 421 extended in a vertical direction within the chamber 41; a turntable 422 provided at an upper end portion of the rotation shaft 421; a chuck 423 provided on an outer peripheral portion of a top surface of the turntable 422 and configured to support an edge portion of the substrate W1; and a driving unit 424 configured to rotate the rotation shaft 421.

The substrate W1 is supported by the chuck 423 to be horizontally held on the turntable 422 while being slightly spaced apart from the top surface of the turntable 422. In the present exemplary embodiment, a mechanism of holding the substrate W1 on the substrate holding unit 42 is of a so-called mechanical chuck type in which the edge portion of the substrate W1 is held by the chuck 423 which is configured to be movable. However, a so-called vacuum chuck type of vacuum attracting a rear surface of the substrate W1 may be used instead.

A base end portion of the rotation shaft 421 is rotatably supported by the driving unit 424, and a leading end portion of the rotation shaft 421 sustains the turntable 422 horizontally. If the rotation shaft 421 is rotated, the turntable 422 placed on the upper end portion of the rotation shaft 421 is rotated, and, as a result, the substrate W1 which is held on the turntable 422 by the chuck 423 is also rotated. The control unit 3 controls the driving unit 424 to adjust, e.g., a rotation timing and a rotational speed of the substrate W1.

The first processing unit 4 includes a first cleaning liquid supply unit 43a, a second cleaning liquid supply unit 43b, a third cleaning liquid supply unit 43c and a rinse liquid supply unit 43d configured to supply a first cleaning liquid L1, a second cleaning liquid L2, a third cleaning liquid L3 and a rinse liquid L4 onto the substrate W1 held on the substrate holding unit 42, respectively.

The first cleaning liquid supply unit 43a is equipped with a nozzle 431a configured to discharge the first cleaning liquid L1 onto the substrate W1 held on the substrate holding unit 42; and a first cleaning liquid supply source 432a configured to supply the first cleaning liquid L1 to the nozzle 431a. The first cleaning liquid L1 is stored in a tank of the first cleaning liquid supply source 432a, and the first cleaning liquid L1 is supplied to the nozzle 431a from the first cleaning liquid supply source 432a through a supply passageway 434a which is equipped with a flow rate controller such as a valve 433a.

The second cleaning liquid supply unit 43b is equipped with a nozzle 431b configured to discharge the second cleaning liquid L2 onto the substrate W1 held on the substrate holding unit 42; and a second cleaning liquid supply source 432b configured to supply the second cleaning liquid L2 to the nozzle 431b. The second cleaning liquid L2 is stored in a tank of the second cleaning liquid supply source 432b, and the second cleaning liquid L2 is supplied to the nozzle 431b from the second cleaning liquid supply source 432b through a supply passageway 434b which is equipped with a flow rate controller such as a valve 433b.

The third cleaning liquid supply unit 43c is equipped with a nozzle 431c configured to discharge the third cleaning liquid L3 onto the substrate W1 held on the substrate holding unit 42; and a third cleaning liquid supply source 432c configured to supply the third cleaning liquid L3 to the nozzle 431c. The third cleaning liquid L3 is stored in a tank of the third cleaning liquid supply source 432c, and the third cleaning liquid L3 is supplied to the nozzle 431c from the third cleaning liquid supply source 432c through a supply passageway 434c which is equipped with a flow rate controller such as a valve 433c.

The rinse liquid supply unit 43d is equipped with a nozzle 431d configured to discharge the rinse liquid L4 onto the substrate W1 held on the substrate holding unit 42; and a rinse liquid supply source 432d configured to supply the rinse liquid L4 to the nozzle 431d. The rinse liquid L4 is stored in a tank of the rinse liquid supply source 432d, and the rinse liquid L4 is supplied to the nozzle 431d from the rinse liquid supply source 432d through a supply passageway 434d which is equipped with a flow rate controller such as a valve 433d.

The first cleaning liquid L1 is selected from a chemical liquid containing hydrogen peroxide and a chemical liquid containing a polar organic solvent. As the chemical liquid containing the hydrogen peroxide, hydrogen peroxide water (aqueous solution of hydrogen peroxide) may be used. A concentration of the hydrogen peroxide water may be set to be in the range from, but not limited to, 1% to 30%. The chemical liquid containing the hydrogen peroxide may contain another component other than the hydrogen peroxide as long as it maintains a cleaning effect of the hydrogen peroxide. As the chemical liquid containing the polar organic solvent, a chemical liquid containing a polar organic solvent such as, but not limited to, N,N-dimethylacetamide (DMAc), N-methyl-2-pyrrolidone (NMP), dimethyl sulfoxide (DMSO), or the like may be used. The chemical liquid containing the polar organic solvent may contain another component other than the polar organic solvent as long as it maintains a cleaning effect of the polar organic solvent. Such another component may be, but not limited to, an organic solvent other than the polar organic solvent, a polar solvent (e.g., water, etc.) other than the polar organic solvent, or the like. In case of using the chemical liquid containing the polar organic solvent as the first cleaning liquid L1, the first cleaning liquid L1 may contain two or more kinds of polar organic solvents.

The second cleaning liquid L2 and the third cleaning liquid L3 are selected from an aqueous solution containing hydrogen fluoride and a strong alkaline aqueous solution. Here, the third cleaning liquid L3 is different from the second cleaning liquid L2. Thus, if the aqueous solution containing the hydrogen fluoride is selected as the second cleaning liquid L2, the strong alkaline aqueous solution may be selected as the third cleaning liquid L3. If the strong alkaline aqueous solution is selected as the second cleaning liquid L2, on the other hand, the aqueous solution containing the hydrogen fluoride is selected as the third cleaning liquid L3. By way of example, dilute hydrofluoric acid (DHF) (aqueous solution of hydrogen fluoride), which is diluted to have a concentration not to corrode the copper wiring of the substrate, may be utilized as the aqueous solution containing the hydrogen fluoride. The aqueous solution containing the hydrogen fluoride may contain another component other than the hydrogen fluoride as long as it maintains a cleaning effect of the hydrogen fluoride. Such another component may be, by way of non-limiting example, ammonia, or the like. The strong alkaline aqueous solution has a pH, for example, higher than pH12. For example, an aqueous solution containing tetramethylammonium hydroxide may be used as the strong alkaline aqueous solution. The strong alkaline aqueous solution may contain another component other than the strong alkaline substance as long as it maintains strong alkaline condition. In case of using the strong alkaline aqueous solution as the second cleaning liquid L2 or the third cleaning liquid L3, the second cleaning liquid L2 or the third cleaning liquid L3 may contain two or more kinds of strong alkaline substances.

The rinse liquid L4 may be, by way of non-limiting example, pure water, isopropyl alcohol (IPA), or the like. The kind of the rinse liquid L4 may be appropriately selected depending on the kind of the cleaning liquid to be rinsed with the rinse liquid L4. If the cleaning liquid is the chemical liquid containing hydrogen peroxide, the aqueous solution containing hydrogen fluoride or the strong alkaline aqueous solution, water may be used as an example of the rinse liquid L4. Meanwhile, if the cleaning liquid is the chemical liquid containing the polar organic solvent, isopropyl alcohol (IPA) may be used as an example of the rinse liquid L4. In this regard, the first processing unit 4 may include a multiple number of rinse liquid supply units configured to supply different kinds of rinse liquids individually. Each rinse liquid supply unit may have the same configuration as the rinse liquid supply unit 43d.

The first processing unit 4 may be further equipped with a drying solvent supply unit including a nozzle configured to discharge a drying solvent such as isopropyl alcohol (IPA) toward the substrate W1 held on the substrate holding unit 42; and a drying solvent supply source configured to supply the drying solvent to the nozzle. Further, the first processing unit 4 may be further equipped with a drying gas supply unit including a nozzle configured to discharge a drying gas such as a nitrogen gas or dry air toward the substrate W1 held on the substrate holding unit 42; and a drying gas supply source configured to supply the drying gas to the nozzle.

The first processing unit 4 includes a nozzle moving mechanism 44 configured to move the nozzles 431a to 431d. The nozzle moving mechanism 44 includes an arm 441; a moving body 442 which is configured to be movable along the arm 441 and has a moving mechanism embedded therein; and a rotating/elevating mechanism 443 configured to rotate and move the arm 441 up and down. The nozzles 431a to 431d are provided at the moving body 442. The nozzle moving mechanism 44 is capable of moving the nozzles 431a to 431d between a position above a central portion of the substrate W1 held on the substrate holding unit 42 and a position above a peripheral portion of the substrate W1, and also capable of moving the nozzles 431a to 431d up to a stand-by position outside a cup 45 to be described later when viewed from the top. In the present exemplary embodiment, though the nozzles 431a to 431d are held by the common arm, they may be configured to be held by different arms and moved independently.

The first processing unit 4 is equipped with the cup 45 having a drain opening 451. The cup 45 is disposed around the substrate holding unit 42, and is configured to collect various kinds of processing liquids (e.g., cleaning liquid, rinse liquid, etc.) which are scattered from the substrate W1. The cup 45 is provided with an elevating mechanism 46 configured to move the cup 45 up and down; and a liquid draining mechanism 47 configured to collect the various kinds of processing liquids scattered from the substrate W1 through the drain opening 251 and drain out them.

<Configuration of Second Processing Unit>

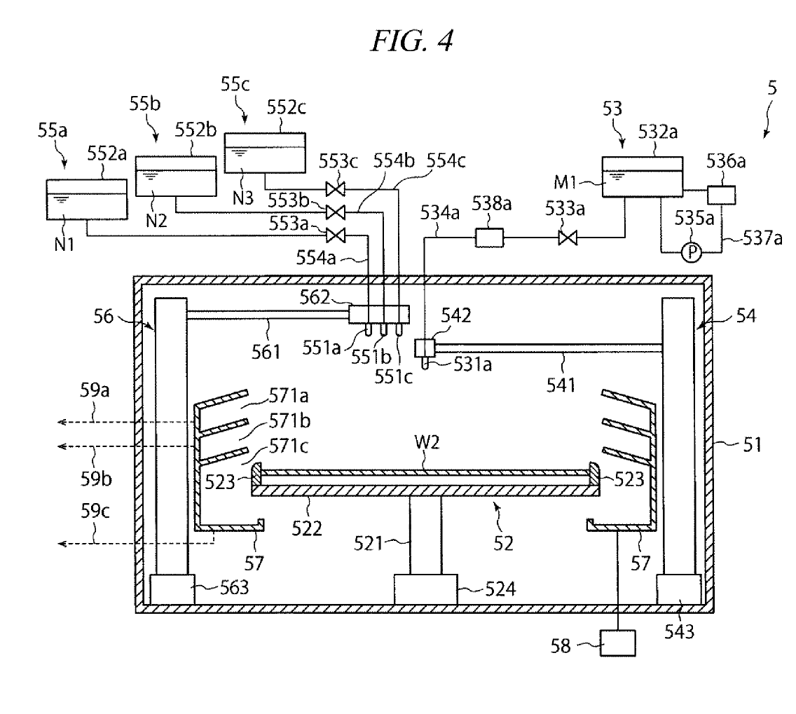

Now, a configuration of the second processing unit 5 will be explained with reference to FIG. 4. FIG. 4 is a schematic cross sectional view illustrating a configuration of a second processing unit 5.

The second processing unit 5 is configured to perform a processing including a plating process of coating the copper wiring 93 of the substrate W2 with a metal film. Accordingly, the second processing unit 5 serves as a plating processing unit. The processing performed by the second processing unit 5 is not particularly limited as long as the plating process is included therein. Thus, the processing performed by the second processing unit 5 may include a process other than the plating process. In the present exemplary embodiment, the plating process is an electroless plating process. Through the electroless plating process, a metal film can be selectively formed on the copper wiring 93 of the substrate W2.

In the present exemplary embodiment, the substrate W2 is a substrate obtained after performing the processing in the first processing unit 4. Thus, the substrate W2 is different from the substrate W1 in that the substrate W2 does not include the organic polymer P. Further, the substrate W2 may be different from the substrate W1 in other ways as well. By way of example, in case that the chemical liquid containing the hydrogen peroxide is used as the first cleaning liquid L1 and the second barrier film 94 is made of Ti or a nitride or oxide thereof (for example, when the second barrier film 94 is a stacked film of Ti/TiN), the second barrier film 94 may be removed from the substrate W1 if the substrate W1 is cleaned with the cleaning liquid L1. In this case, the substrate W2 is also different from the substrate W1 in that the substrate W2 does not include the second barrier film 94.

The second processing unit 5 includes a chamber 51, and is configured to perform a substrate processing including the plating process within the chamber 51.

The second processing unit 5 is provided with a substrate holding unit 52. The substrate holding unit 52 includes a rotation shaft 521 extended in a vertical direction within the chamber 51; a turntable 522 provided at an upper end portion of the rotation shaft 521; a chuck 523 provided on an outer peripheral portion of a top surface of the turntable 522 and configured to support an edge portion of the substrate W2; and a driving unit 524 configured to rotate the rotation shaft 521.

The substrate W2 is supported by the chuck 523 to be horizontally held on the turntable 522 while being slightly spaced apart from the top surface of the turntable 522. In the present exemplary embodiment, a mechanism of holding the substrate W2 on the substrate holding unit 52 is of a so-called mechanical chuck type in which the edge portion of the substrate W2 is held by the chuck 523 which is configured to be movable. However, a so-called vacuum chuck type of vacuum attracting a rear surface of the substrate W2 may be used instead.

A base end portion of the rotation shaft 521 is rotatably supported by the driving unit 524, and a leading end portion of the rotation shaft 521 sustains the turntable 522 horizontally. If the rotation shaft 521 is rotated, the turntable 522 placed on the upper end portion of the rotation shaft 521 is rotated, and, as a result, the substrate W2 which is held on the turntable 522 by the chuck 523 is also rotated. The control unit 3 controls the driving unit 524 to adjust, e.g., a rotation timing and a rotational speed of the substrate W2.

The second processing unit 5 includes a plating liquid supply unit 53 configured to supply a plating liquid M1 onto the substrate W2 which is held on the substrate holding unit 52. The plating liquid supply unit 53 is equipped with a nozzle 531a configured to discharge the plating liquid M1 toward the substrate W2 held on the substrate holding unit 52; and a plating liquid supply source 523a configured to supply the plating liquid M1 to the nozzle 531a. The plating liquid M1 is stored in a tank of the plating liquid supply source 532a, and the plating liquid M1 is supplied into the nozzle 531a from the plating liquid supply source 532a through a supply passageway 534a which is equipped with a flow rate controller such as a valve 533a.

The plating liquid M1 is an autocatalytic (reduction) plating liquid for electroless plating. The plating liquid M1 contains a metal ion such as a cobalt (Co) ion, a nickel (Ni) ion, or a tungsten (W) ion; and a reducing agent such as hypophosphorous acid or dimethylamineborane. Further, in the autocatalytic (reduction) electroless plating, the metal ion in the plating liquid M1 is reduced by the electrons emitted in an oxidation reaction of the reducing agent in the plating liquid Ml, so that a metal film is precipitated. The plating liquid M1 may further contain an additive or the like. The metal film (plating film) formed by the plating process using the plating liquid M1 may be, by way of non-limiting example, CoWB, CoB, CoWP, CoWBP, NiWB, NiB, NiWP, NiWBP, or the like. By containing the tungsten (W) in the plating film, the plating film can obtain barrier property capable of suppressing diffusion of copper atoms contained in the copper wiring 93. P in the plating film is originated from the reducing agent (e.g., hypophosphorous acid) containing P, and B in the plating film is originated from the reducing agent (e.g., dimethylamineborane) containing B.

A circulation passageway 537a provided with a pump 535a and a first heating unit 536a is connected to the tank of the plating liquid supply source 532a. The plating liquid M1 in the tank is heated to a storage temperature while being circulated through the circulation passageway 537a. Here, the “storage temperature” refers to a temperature higher than a room temperature and lower than a temperature (plating temperature) where the precipitation of the metal ion progresses through a self-reaction in the plating liquid Ml.

The supply passageway 534a is provided with a second heating unit 538a configured to heat the plating liquid M1 to a discharge temperature higher than the storage temperature. The second heating unit 538a is further configured to heat the plating liquid Ml, which has been heated to the storage temperature by the first heating unit 536a, up to the discharge temperature. Here, the “discharge temperature” refers to a temperature equal to or higher than the aforementioned plating temperature.

In the present exemplary embodiment, the plating liquid M1 is heated to a temperature equal to or higher than the plating temperature in two stages by the first heating unit 536a and the second heating unit 538a. Thus, as compared to the case where the plating liquid M1 is heated to the temperature higher than the plating temperature within the tank, evaporation of the components, deactivation of the reducing agent in the plating liquid M1 or the like can be suppressed. Therefore, a lifetime of the plating liquid M1 can be lengthened. Further, as compared to the case where the plating liquid M1 is stored at the room temperature within the tank and then heated to the temperature equal to or higher than the plating temperature by the second heating unit 538a later, it is possible to heat the plating liquid M1 to the temperature equal to or higher than the plating liquid rapidly with small energy, so that the precipitation of the metal ion can be suppressed.

Various kinds of chemical liquids are supplied into the tank of the plating liquid supply source 532a from a multiple number of chemical liquid supply sources (not shown) which store various kinds of components of the plating liquid M1. By way of example, chemical liquids such as a CoSO₄ metal salt containing a Co ion, a reducing agent (e.g., hypophosphorous acid, etc.), and an additive are supplied. At this time, flow rates of these chemical liquids are adjusted such that the components of the plating liquid M1 stored in the tank are appropriately controlled. A degassing unit (not shown) configured to remove dissolved oxygen and dissolved hydrogen in the plating liquid M1 may be provided in the tank. The degassing unit is configured to supply an inert gas such as, but not limited to, a nitrogen gas into the tank and dissolve the inert gas such as the nitrogen gas in the plating liquid M1, so that the other gases such as the oxygen and the hydrogen previously dissolved in the plating liquid M1 may be discharged to the outside of the plating liquid M1. The gases such as the oxygen and the hydrogen discharged from the plating liquid M1 may be exhausted from the tank by an exhaust unit (not shown). The circulation passageway 537a may be provided with a filter (not shown). By providing the filter in the circulation passageway 537a, various kinds of impurities contained in the plating liquid M1 can be removed when the plating liquid M1 is heated by the first heating unit 536a. The circulation passageway 537a may be further provided with a monitoring unit (not shown) configured to monitor a characteristic of the plating liquid M1. The monitoring unit may be implemented by, for example, a temperature monitoring unit configured to monitor a temperature of the plating liquid M1, a pH monitoring unit configured to monitor a pH of the plating liquid M1, or the like.

The second processing unit 5 is equipped with a nozzle moving mechanism 54 configured to move the nozzle 531a. The nozzle moving mechanism 54 includes an arm 541; a moving body 542 which is configured to be movable along the arm 541 and has a moving mechanism embedded therein; and a rotating/elevating mechanism 543 configured to rotate and move the arm 541 up and down. The nozzle 531a is provided at the moving body 542. The nozzle moving mechanism 54 is capable of moving the nozzle 531a between a position above a central portion of the substrate W2 held on the substrate holding unit 52 and a position above a peripheral portion of the substrate W2, and also capable of moving the nozzle 531a up to a stand-by position outside a cup 57 to be described later when viewed from the top.

The second processing unit 5 includes a catalyst solution supply unit 55a, a cleaning liquid supply unit 55b and a rinse liquid supply unit 55c configured to supply a catalyst solution N1, a cleaning liquid N2 and a rinse liquid N3 onto the substrate W2 held on the substrate holding unit 52, respectively. Further, it may be appropriately determined depending on the kind of the plating liquid M1 whether to provide the catalyst solution supply unit 55a. That is, depending on the kind of the plating liquid M1, the catalyst solution supply unit 55a may be omitted.

The catalyst solution supply unit 55a includes a nozzle 551a configured to discharge the catalyst solution N1 onto the substrate W2 held on the substrate holding unit 52; and a catalyst solution supply source 552a configured to supply the catalyst solution N1 to the nozzle 551a. The catalyst solution N1 is stored in a tank of the catalyst solution supply source 552a, and the catalyst solution N1 is supplied to the nozzle 551a from the catalyst solution supply source 552a through a supply passageway 554a which is provided with a flow rate controller such as a valve 553a.

The cleaning liquid supply unit 55b includes a nozzle 551b configured to discharge the cleaning liquid N2 onto the substrate W2 held on the substrate holding unit 52; and a cleaning liquid supply source 552b configured to supply the cleaning liquid N2 to the nozzle 551b. The cleaning liquid N2 is stored in a tank of the cleaning liquid supply source 552b, and the cleaning liquid N2 is supplied to the nozzle 551b from the cleaning liquid supply source 552b through a supply passageway 554b which is provided with a flow rate controller such as a valve 553b.

The rinse liquid supply unit 55c includes a nozzle 551c configured to discharge the rinse liquid N3 onto the substrate W2 held on the substrate holding unit 52; and a rinse liquid supply source 552c configured to supply the rinse liquid N3 to the nozzle 551c. The rinse liquid N3 is stored in a tank of the rinse liquid supply source 552c, and the rinse liquid N3 is supplied to the nozzle 551c from the rinse liquid supply source 552c through a supply passageway 554c which is provided with a flow rate controller such as a valve 553c.

The catalyst solution N1, the cleaning liquid N2 and the rinse liquid N3 are pre-treatment liquids for preprocessings that are performed prior to the plating process using the plating liquid M1.

The catalyst solution N1 contains a metal ion (e.g., a palladium (Pd) ion) having catalytic activity to an oxidation reaction of the reducing agent in the plating liquid M1. In the electroless plating process, in order to start precipitation of the metal ion in the plating liquid M1, an initial film surface (that is, surface of the copper wiring 93) needs to have sufficient catalytic activity to the oxidation reaction of the reducing agent in the plating liquid M1. However, the catalytic activity of the copper is low. Thus, depending on the kind of the plating liquid M1, it may be desirable to process the surface of the copper wiring 93 with the catalytic solution N1 and form a metal film having the catalytic activity on the surface of the copper wiring 93 before starting the plating process with the plating liquid M1. It may be appropriately determined depending on the kind of the plating liquid M1 whether to perform the processing with the catalyst solution N1 before starting the plating process. That is, depending on the kind of the plating liquid M1, the processing with the catalyst solution N1 may be omitted. The metal film having the catalytic activity is formed through a replacement reaction. In the replacement reaction, copper in the copper wiring 93 serves as the reducing agent, and the metal ion (e.g., Pd ion) in the catalyst solution N1 is reduced to be precipitated on the copper wiring 93. Since this replacement reaction does not occur in the first barrier film 92 and the second barrier film 94, the electroless plating reaction takes place only on the surface of the copper wiring 93. Therefore, it is possible to form the plating film on the surface of the copper wiring 93 selectively through the electroless plating reaction.

As an example of the cleaning liquid N2, a malic acid, a succinic acid, a citric acid, a malonic acid, or the like may be used.

As an example of the rinse liquid N3, pure water may be used.

The second processing unit 5 includes a nozzle moving mechanism 56 configured to move the nozzles 551a to 551c. The nozzle moving mechanism 56 is equipped with an arm 561; a moving body 562 which is configured to be movable along the arm 561 and has a moving mechanism embedded therein; and a rotating/elevating mechanism 563 configured to rotate and move the arm 561 up and down. The nozzles 551a to 551c are provided at the moving body 562. The nozzle moving mechanism 56 is capable of moving the nozzles 551a to 551c between a position above the central portion of the substrate W2 held on the substrate holding unit 52 and a position above the peripheral portion of the substrate W2, and also capable of moving the nozzles 551a to 551c up to a stand-by position outside the cup 57 to be described later when viewed from the top. In the present exemplary embodiment, though the nozzles 551a to 551c are held by the common arm, they may be configured to be held by different arms and moved independently.

The second processing unit 5 is equipped with the cup 57 having drain openings 571a, 571b and 571c. The cup 57 is disposed around the substrate holding unit 52, and is configured to collect various kinds of processing liquids (e.g., plating liquid, catalyst solution, cleaning liquid, rinse liquid, etc.) which are scattered from the substrate W2. The cup 57 is provided with an elevating mechanism 58 configured to move the cup 57 up and down; and liquid draining mechanisms 59a, 59b and 59c configured to collect and drain the various kinds of processing liquids scattered from the substrate W2 through the drain openings 571a, 571b and 571c, respectively. By way of example, the plating liquid M1 scattered from the substrate W2 is drained from the liquid draining mechanism 59a; the catalyst solution N1 scattered from the substrate W2 is drained from the liquid draining mechanism 59b; and the cleaning liquid N2 and the rinse liquid N3 scattered from the substrate W2 are drained from the liquid draining mechanism 59c.

<Substrate Processing Method>

Now, a substrate processing method performed by the substrate processing apparatus 1 will be discussed. The substrate processing method performed by the substrate processing apparatus 1 includes a cleaning process of removing, from a substrate W1 on which a dry etching process has been performed, an organic polymer P adhering to a surface of the substrate W1; and a plating process of coating a copper wiring 93 of a substrate W2, on which the cleaning process has been performed, with a metal film. The cleaning processing in the cleaning process is performed by the first processing unit 4, and the plating processing in the plating process is performed by the second processing unit 5. An operation of the first processing unit 4 and an operation of the second processing unit 5 are controlled by the control unit 3. The substrate processing method performed by the substrate processing apparatus 1 may include the dry etching process.

The substrate W1 as a cleaning target in the cleaning process is a substrate obtained after performing the dry etching process. An example of a manufacturing process of the substrate W1 is illustrated in FIG. 5A to FIG. 5D.

First, a source substrate W0 shown in FIG. 5A is prepared. The source substrate W0 includes a semiconductor wafer S; an interlayer insulating film 91 formed on the semiconductor wafer S; a first barrier film 92′ formed on the interlayer insulating film 91; a copper film 93′ formed on the first barrier film 92′; and a second barrier film 94′ formed on the copper film 93′. These various kinds of films may be formed by using a commonly known method such as a PVD method, a CVD method, a sputtering method, or the like.

As depicted in FIG. 5B, an etching hard mask 95 is formed on the second barrier film 94′ of the source substrate W0. The etching hard mask 95 is formed to have a pattern corresponding to a pattern of a copper wiring 93. The etching hard mask 95 may be formed by using a commonly known method such as a photolithography method, or the like.

Then, as depicted in FIG. 5C, the first barrier film 92′, the copper film 93′ and the second barrier film 94′ are processed by a dry etching process with the etching hard mask 95 as a mask. This dry etching process may be an anisotropic etching process or an isotropic etching process, and, desirably, the anisotropic etching process. As an example of an etching method performed in the dry etching process, an ECR etching method, an ICP etching method, a CCP etching method, a Helicon etching method, a TCP etching method, a UHF plasma method, a SWP etching method, or the like may be used.

The copper film 93′ is patterned to have a preset wiring shape by the dry etching process, so that the copper wiring 93 a part of which is exposed on a surface of the substrate is formed, as shown FIG. 5C.

An etching gas excited into plasma is used in the dry etching process. As an example of the etching gas, an organic etching gas, for example, one or more kinds of organic etching gases selected from, but not limited to, a methane gas, a CF-based gas, a carboxylic acid-based gas containing a methyl group and an alcohol-based gas is used.

As an example of the CF-based gas (carbon fluoride-based gas), one or more kinds of gases selected from, but not limited to, CF₄, CHF₃, C₃F₈, and C₄F₈ may be used.

The carboxylic acid-based gas is a gas containing a carboxylic acid represented by R—COOH (R denotes hydrogen or an alkenyl group or an alkyl group of C₁ to C₂₀ having a straight chain structure or a branched chain structure). The carboxylic acid may be, by way of example, an acetic acid or a propionic acid.

The alcohol-based gas is a gas containing alcohol represented by R—OH (R denotes an alkenyl group or an alkyl group of C₁ to C₂₀ having a straight chain structure or a branched chain structure). The alcohol may be, by way of non-limiting example, methanol, ethanol, n-propanol, isopropanol, n-butanol, isobutanol, or t-butanol.

In the dry etching process using the organic etching gas, e.g., the one or more kinds of organic etching gases selected from the methane gas, the CF-based gas, the carboxylic acid-based gas containing the methyl group and the alcohol-based gas, an organic polymer P originated from the organic etching gas, e.g., the one or more kinds of organic etching gases selected from the methane gas, the CF-based gas, the carboxylic acid-based gas containing the methyl group and the alcohol-based gas is generated by excitation of the organic etching gas into plasma, and the generated organic polymer P adheres to the surface of the substrate W1, as depicted in FIG. 5D.

The substrate W1 obtained after performing the dry etching process is carried into the first processing unit 4. At this time, the transfer device 213 takes out the substrate W1 from the carrier C placed in the placing section 211 and places the substrate W1 in the delivery unit 214. The transfer device 222 takes out the substrate W1 from the delivery unit 214 and carries the substrate W1 into the first processing unit 4.

The substrate W1 which is carried into the first processing unit 4 is held on the substrate holding unit 42. At this time, the substrate holding unit 42 holds the substrate W1 on the turntable 422 horizontally while the edge portion of the substrate W1 is supported by the chuck 423. The driving unit 424 rotates the substrate W1 held on the substrate holding unit 42 at a preset speed. The control unit 3 controls the driving unit 424 to adjust, e.g., a rotation timing and a rotation speed of the substrate W1.

In the first processing unit 4, the cleaning process is performed on the substrate W1 which is held on the substrate holding unit 42. The cleaning process includes a first cleaning process of cleaning the substrate W1 with a first cleaning liquid L1, a second cleaning process of cleaning the substrate W1 with a second cleaning liquid L2 and a third cleaning process of cleaning the substrate W1 with a third cleaning liquid L3.

In the first cleaning process, while rotating the substrate W1 held on the substrate holding unit 42 at a preset speed, the nozzle 431a of the first cleaning liquid supply unit 43a is placed at a position above a central portion of the substrate W1, and the first cleaning liquid L1 is supplied onto the substrate W1 from the nozzle 431a. At this time, the control unit 3 controls the first cleaning liquid supply unit 43a to adjust, e.g., a supply timing, a supply time and a supply amount of the first cleaning liquid L1. The first cleaning liquid L1 supplied on the substrate W1 is diffused onto the surface of the substrate W1 by a centrifugal force generated when the substrate W1 is rotated. As a result, the organic polymer P attached to the substrate W1 is removed from the substrate W1. Further, in case that a chemical liquid containing hydrogen peroxide is used as the first cleaning liquid L1 and the second barrier film 94 is made of Ti or a nitride or oxide thereof (e.g., if the second barrier film 94 is a stacked film of Ti/TiN), the second barrier film 94 may be removed through the first cleaning process.

The second cleaning process is performed after the first cleaning process. In the second cleaning process, while rotating the substrate W1 held on the substrate holding unit 42 at a preset speed, the nozzle 431b of the second cleaning liquid supply unit 43b is placed at the position above the central portion of the substrate W1, and the second cleaning liquid L2 is supplied onto the substrate W1 from the nozzle 431b. At this time, the control unit 3 controls the second cleaning liquid supply unit 43b to adjust, e.g., a supply timing, a supply time and a supply amount of the second cleaning liquid L2. The second cleaning liquid L2 supplied on the substrate W1 is diffused onto the surface of the substrate W1 by a centrifugal force generated when the substrate W1 is rotated. As a result, the organic polymer P remaining on the substrate W1 is removed. Though the second cleaning process can be omitted, it may be desirable to perform the second cleaning process after the first cleaning process in order to improve the effect of removing the organic polymer P.

The third cleaning process is performed after the second cleaning process. In the third cleaning process, while rotating the substrate W1 held on the substrate holding unit 42 at a preset speed, the nozzle 431c of the third cleaning liquid supply unit 43c is placed at the position above the central portion of the substrate W1, and the third cleaning liquid L3 is supplied onto the substrate W1 from the nozzle 431c. At this time, the control unit 3 controls the third cleaning liquid supply unit 43c to adjust, e.g., a supply timing, a supply time and a supply amount of the third cleaning liquid L3. The third cleaning liquid L2 supplied on the substrate W1 is diffused onto the surface of the substrate W1 by a centrifugal force generated when the substrate W1 is rotated. As a result, the organic polymer P remaining on the substrate W1 is removed. Though the third cleaning process can be omitted, it may be desirable to perform the third cleaning process after the second cleaning process in order to improve the effect of removing the organic polymer P.

It is desirable to perform a first rinse process of rinsing the substrate W1 with a rinse liquid L4 in the first processing unit 4 after the first cleaning process and before the second cleaning process. In the first rinse process, while rotating the substrate W1 held on the substrate holding unit 42 at the preset speed, the nozzle 431d of the rinse liquid supply unit 43d is placed at the position above the central portion of the substrate W1, and the rinse liquid L4 is supplied onto the substrate W1 from the nozzle 431d. At this time, the control unit 3 controls the rinse liquid supply unit 43d to adjust, e.g., a supply timing, a supply time and a supply amount of the rinse liquid L4. The rinse liquid L4 supplied on the substrate W1 is diffused onto the surface of the substrate W1 by the centrifugal force generated when the substrate W1 is rotated. As a result, the first cleaning liquid L1 remaining on the substrate W1 is washed away. The kind of the rinse liquid L4 used in the first rinse process may be appropriately selected depending on the kind of the first cleaning liquid L1. In case that the first cleaning liquid L1 is the chemical liquid containing hydrogen peroxide, the water may be used as the rinse liquid L4, for example. In case that the first cleaning liquid L1 is the chemical liquid containing the polar organic solvent, isopropyl alcohol (IPA) may be used as the rinse liquid L4, for example.

It is desirable to perform a second rinse process of rinsing the substrate W1 with the rinse liquid L4 in the first processing unit 4 after the second cleaning process and before the third cleaning process. The second rinse process may be performed in the same way as the first rinse process. The second cleaning liquid L2 remaining on the substrate W1 is washed away through the second rinse process. The kind of the rinse liquid L4 used in this second rinse process may be appropriately selected depending on the kind of the second cleaning liquid. In case that the second cleaning liquid L2 is the aqueous solution containing hydrogen fluoride or the strong alkaline aqueous solution, water may be used as the rinse liquid L4, for example.

It is desirable to perform a third rinse process of rinsing the substrate W1 with the rinse liquid L4 in the first processing unit 4 after the third cleaning process. The third rinse process may be performed in the same way as the first rinse process. The third cleaning liquid L3 remaining on the substrate W1 is washed away through the third rinse process. The kind of the rinse liquid L4 used in this third rinse process may be appropriately selected depending on the kind of the third cleaning liquid. In case that the third cleaning liquid L3 is the aqueous solution containing hydrogen fluoride or the strong alkaline aqueous solution, water may be used as the rinse liquid L4, for example.

After a final cleaning process (or after a rinse process if the rinse process is performed after the final cleaning process), it is desirable to perform a drying process of drying the substrate W1 in the first processing unit 4. In the drying process, the substrate W1 can be dried naturally by rotating the substrate W1, or by discharging a drying solvent or a drying gas to the substrate W1.

A substrate W2 obtained after performing the substrate processing in the first processing unit 4 is carried into the second processing unit 5. At this time, the transfer device 222 takes out the substrate W2 from the first processing unit 4 and carries the substrate W2 into the second processing unit 5.

The substrate W2 carried into the second processing unit 5 is held on the substrate holding unit 52. At this time, the substrate holding unit 52 holds the substrate W2 on the turntable 522 horizontally while supporting the edge portion of the substrate W2 by the chuck 523. The driving unit 524 rotates the substrate W2 held on the substrate holding unit 52 at a preset speed.

The plating process in the second processing unit 5 is performed on the substrate W2 which is held on the substrate holding unit 52. In the second processing unit 5, a pre-treatment of pre-processing the substrate W2 may be performed prior to the plating process. The pre-treatment may include a cleaning process and a first rinse process which is performed after the cleaning process. The pre-treatment may further include a catalyst solution supplying process which is performed after the first rinse process. Additionally, the pre-treatment may further include a second rinse process which is performed after the catalyst solution supplying process.

In the cleaning process, while rotating the substrate W2 held on the substrate holding unit 52 at a preset speed, the nozzle 551b of the cleaning liquid supply unit 55b is placed at a position above the central portion of the substrate W2, and the cleaning liquid N2 is supplied onto the substrate W2 from the nozzle 551b. At this time, the control unit 3 controls the cleaning liquid supply unit 55b to adjust, e.g., a supply timing, a supply time and a supply amount of the cleaning liquid N2. The cleaning liquid N2 supplied on the substrate W2 is diffused onto the surface of the substrate W2 by a centrifugal force generated when the substrate W2 is rotated. As a result, an oxide film formed on the copper wiring 93 when the substrate W2 is transferred into the second processing unit 5 from the first processing unit 4, a deposit attached to the substrate W2 when the substrate W2 is transferred into the second processing unit 5 from the first processing unit 4, or the like is removed from the substrate W2. The cleaning liquid N2 scattered from the substrate W2 is drained through the drain opening 571c of the cup 57 and the liquid draining mechanism 59c.

In the first rinse process, while rotating the substrate W2 held on the substrate holding unit 52 at a preset speed, the nozzle 551c of the rinse liquid supply unit 55c is located at the position above the central portion of the substrate W2, and the rinse liquid N3 is supplied onto the substrate W2 from the nozzle 551c. At this time, the control unit 3 controls the rinse liquid supply unit 55c to adjust, e.g., a supply timing, a supply time and a supply amount of the rinse liquid N3. The rinse liquid N3 supplied on the substrate W2 is diffused onto the surface of the substrate W2 by a centrifugal force generated when the substrate W2 is rotated. As a result, the cleaning liquid N2 remaining on the substrate W2 is washed away. The rinse liquid N3 scattered from the substrate W2 is drained through the drain opening 571c of the cup 57 and the liquid draining mechanism 59c.

In the catalyst solution supplying process, while rotating the substrate W2 held on the substrate holding unit 52 at a preset speed, the nozzle 551a of the catalyst solution supply unit 55a is placed at the position above the central portion of the substrate W2, and the catalyst solution N1 is supplied onto the substrate W2 from the nozzle 551a. At this time, the control unit 3 controls the catalyst solution supply unit 55a to adjust, e.g., a supply timing, a supply time and a supply amount of the catalyst solution N1 of. The catalyst solution N1 supplied on the substrate W2 is diffused onto the surface of the substrate W2 by a centrifugal force generated when the substrate W2 is rotated. As a result, a metal film (e.g., Pd film) having catalytic activity is formed on the copper wiring 93 of the substrate W2. The catalyst solution N1 scattered from the substrate W2 is drained through the drain opening 571b of the cup 57 and the liquid draining mechanism 59b.

In the second rinse process, while rotating the substrate W2 held on the substrate holding unit 52 at a preset speed, the nozzle 551c of the rinse liquid supply unit 55c is placed at the position above the central portion of the substrate W2, and the rinse liquid N3 is supplied onto the substrate W2 from the nozzle 551c. At this time, the control unit 3 controls the rinse liquid supply unit 55c to adjust, e.g., a supply timing, a supply time and a supply amount of the rinse liquid N3. The rinse liquid N3 supplied on the substrate W2 is diffused onto the surface of the substrate W2 by a centrifugal force generated when the substrate W2 is rotated. As a result, the catalyst solution N1 remaining on the substrate W2 is washed away. The rinse liquid N3 scattered from the substrate W2 is drained through the drain opening 571c of the cup 57 and the liquid draining mechanism 59c.

In the plating process, while rotating the substrate W2 held on the substrate holding unit 52 at a preset speed, the nozzle 531a of the plating liquid supply unit 53 is placed at the position above the central portion of the substrate W2, and the plating liquid M1 is supplied onto the substrate W2 from the nozzle 531a. At this time, the control unit 3 controls the plating liquid supply unit 53 to adjust, e.g., a supply timing, a supply time and a supply amount of the plating liquid M1. The plating liquid M1 supplied on the substrate W2 is diffused onto the surface of the substrate W2 by a centrifugal force generated when the substrate W2 is rotated. As a result, a plating film is formed on the copper wiring 93 of the substrate W2 (or on the metal film (e.g., Pd film) which is formed on the copper wiring 93 of the substrate W2 and has the catalytic activity in case that the catalyst solution supplying process is performed). The plating liquid M1 scattered from the substrate W2 is drained through the drain opening 571a of the cup 57 and the liquid draining mechanism 59a.

A supply amount and a supply time of the plating liquid M1 in the plating process are appropriately adjusted depending on a thickness of the plating film to be formed. For example, by supplying the plating liquid M1 onto the substrate W2, an initial plating film can be formed on the copper wiring 93 of the substrate W2 (on the metal film (e.g., Pd film) which is formed on the copper wiring 93 of the substrate W2 and has the catalytic activity, in case that the catalyst solution supplying process is performed). By continuing to supply the plating liquid M1 onto the substrate W2, a plating reaction further progresses on the initial plating film, so that a plating film having a required thickness is obtained.

In the second processing unit 5, it is desirable to perform a drying process of drying the substrate W2 after the plating process. In the drying process, the substrate W2 can be dried naturally by rotating the substrate W2 or by discharging a drying solvent or a drying gas to the substrate W2.

A substrate W3 obtained after performing the substrate processing in the second processing unit 5 is carried out from the second processing unit 5. At this time, the transfer device 222 takes out the substrate W3 from the second processing unit 5 and places the substrate W3 in the delivery unit 214. The transfer device 213 takes out the substrate W3 which is placed in the delivery unit 214 by the transfer mechanism 222, and accommodates the substrate W3 in the carrier C of the placing section 211.

The above-described exemplary embodiment can be modified in various ways. Now, modification examples of the exemplary embodiment will be explained. Further, it is possible to combine two or more of the following modification examples.

### FIRST MODIFICATION EXAMPLE

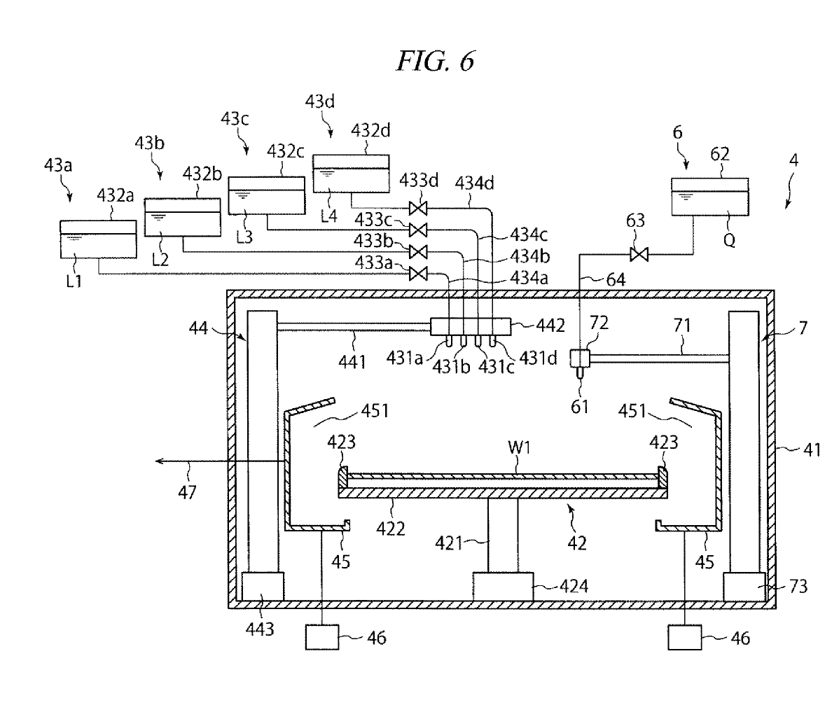

A first modification example will be described with reference to FIG. 6.

As depicted in FIG. 6, the first processing unit 4 may be equipped with a hydrophobizing agent solution supply unit 6 configured to supply a hydrophobizing agent solution Q onto the substrate W1 held on the substrate holding unit 42.

The hydrophobizing agent solution supply unit 6 is equipped with a nozzle 61 configured to discharge the hydrophobizing agent solution Q onto the substrate W1 held on the substrate holding unit 42; and a hydrophobizing agent solution supply source 62 configured to supply the hydrophobizing agent solution Q to the nozzle 61. The hydrophobizing agent solution Q is stored in a tank of the hydrophobizing agent solution supply source 62, and the hydrophobizing agent solution Q is supplied to the nozzle 61 from the hydrophobizing agent solution supply source 62 through a supply passageway 64 which is provided with a flow rate controller such as a valve 63.

The hydrophobizing agent solution Q contains a hydrophobizing agent. By way of non-limiting example, the hydrophobizing agent may be a silane coupling agent, a silylating agent, or the like. As an example of the silane coupling agent, methyltrimethoxysilane or methyltriethoxysilane may be used. As an example of the silylating agent, N-(trimethylsilyl)dimethylamine, bis(trimethylsilyl)amine, or the like may be used. A concentration of the hydrophobizing agent in the hydrophobizing agent solution Q may be in the range from, for example, 0.01% to 100%. As an example of a solvent of the hydrophobizing agent solution, propylene glycol monomethyl ether acetate (PGMEA), cyclohexanon, isopropyl alcohol, or the like may be used.

As illustrated in FIG. 6, the first processing unit 4 may further include a nozzle moving mechanism 7 configured to move the nozzle 61. The nozzle moving mechanism 7 includes an arm 71; a moving body 72 which is configured to be movable along the arm 71 and has a moving mechanism embedded therein; and a rotating/elevating mechanism 73 configured to rotate and move the arm 71 up and down. The nozzle 61 is provided at the moving body 72. The nozzle moving mechanism 7 is capable of moving the nozzle 61 between a position above the central portion of the substrate W1 held on the substrate holding unit 42 and a position above the peripheral portion of the substrate W1, and also capable of moving the nozzle 61 up to a stand-by position outside the cup 45 when viewed from the top.

In the first modification example, a hydrophobizing agent solution supplying process of supplying the hydrophobizing agent solution onto the substrate W1 held on the substrate holding unit 42 is performed by the hydrophobizing agent solution supply unit 6 in the first processing unit 4. The hydrophobizing agent solution supplying process is performed after a final cleaning process (or after a rinse process if the rinse process is performed after the final cleaning process) in the first processing unit 4. By way of example, the hydrophobizing agent solution supplying process is performed after the third cleaning process (or after the third rinse process if the third rinse process is performed after the third cleaning process) in the first processing unit 4.

In the hydrophobizing agent solution supplying process, while rotating the substrate W1 held on the substrate holding unit 41 at a preset speed, the nozzle 61 of the hydrophobizing agent solution supply unit 6 is moved to the position above the central portion of the substrate W1, and the hydrophobizing agent solution Q is supplied onto the substrate W1 from the nozzle 61. At this time, the control unit 3 controls the hyrophobizing agent solution supply unit 6 to adjust, e.g., a supply timing, a supply time and a supply amount of the hydrophobizing agent solution Q. The hydrophobizing agent solution Q supplied on the substrate W1 is diffused onto the surface of the substrate W1 by a centrifugal force generated as the substrate W1 is rotated. As a result, the surface of the substrate W1 is covered with the hydrophobizing agent solution.

By drying the hydrophobizing agent solution, a hydrophobic film is formed on the surface of the substrate W1. The hydrophobic film is configured to suppress oxidation of the copper wiring 93 that might occur when the substrate W2 is transferred into the second processing unit 5 from the first processing unit 4. The hydrophobizing agent solution may be dried naturally by rotating the substrate W1, or by discharging a drying solvent or a drying gas to the substrate W1.

The substrate W2 having the hydrophobic film formed thereon is sent into the second processing unit 5, as in the above-described exemplary embodiment, and a pre-treatment and a plating process are performed in the second processing unit 5. Further, since the hydrophobic film can be removed with a cleaning liquid used in the pre-treatment and a plating liquid used in the plating process performed in the second processing unit 5, an additional process for removing the hydrophobic film need not be performed.

In the first modification example, the hydrophobizing agent solution supply unit 6 is provided within the chamber 41 of the first processing unit 4, and the hydrophobizing agent solution supplying process is performed within the chamber 41. However, the hydrophobizing agent solution supply unit 6 may be provided in a chamber different from the chamber 41 of the first processing unit 4. In such a case, a substrate holding unit having the same configuration as the substrate holding unit 42 is provided within the chamber in which the hydrophobizing agent solution supply unit 6 is provided, and the hydrophobizing agent solution supplying process is performed after a final cleaning process (or after a rinse process if the rinse process is performed after the final cleaning process) in the first processing unit 4 and before the transfer into the second processing unit 5.

### SECOND MODIFICATION EXAMPLE

In the above-described exemplary embodiment, the plating process is performed as the coating process of coating the copper wiring 93 of the substrate W2, which is obtained after performing the cleaning process, with the metal film. However, the plating process may be another coating process. The coating process is not particularly limited as long as the copper wiring of the substrate can be coated with a metal film. Such another coating process may be, for example, a CVD process. Furthermore, the hydrophobic film formed in the first modification example can be removed through a plasma process in the CVD process.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting.

We claim:

1. A substrate processing apparatus including a cleaning processing unit configured to perform a cleaning process of removing, from a substrate having a copper wiring formed by a dry etching process using an organic etching gas, an organic polymer which is originated from the organic etching gas and generated in the dry etching process and adheres to a surface of the substrate; and a control unit configured to control an operation of the cleaning processing unit,
wherein the cleaning processing unit comprises a first cleaning liquid supply unit configured to supply a first cleaning liquid selected from a chemical liquid containing hydrogen peroxide and a chemical liquid containing a polar organic solvent onto the substrate, and
the control unit controls the first cleaning liquid supply unit such that the first cleaning liquid is supplied onto the substrate by the first cleaning liquid supply unit.

2. The substrate processing apparatus of claim 1,
wherein the organic etching gas is one or more kinds of gases selected from a methane gas, a CF-based gas, a carboxylic acid-based gas containing a methyl group and an alcohol-based gas.

3. The substrate processing apparatus of claim 1,
wherein the cleaning processing unit further comprises a second cleaning liquid supply unit configured to supply a second cleaning liquid, which is selected from an aqueous solution containing hydrogen fluoride and a strong alkaline aqueous solution, onto the substrate, and
the control unit controls the first cleaning liquid supply unit and the second cleaning liquid supply unit such that the second cleaning liquid is supplied onto the substrate by the second cleaning liquid supply unit after the first cleaning liquid is supplied by the first cleaning liquid supply unit.

4. The substrate processing apparatus of claim 3,
wherein the cleaning processing unit further comprises a third cleaning liquid supply unit configured to supply a third cleaning liquid which is selected from an aqueous solution containing hydrogen fluoride and a strong alkaline aqueous solution and is different from the second cleaning liquid, and
the control unit controls the first cleaning liquid supply unit, the second cleaning liquid supply unit and the third cleaning liquid supply unit such that the third cleaning liquid is supplied onto the substrate by the third cleaning liquid supply unit after the second cleaning liquid is supplied by the second cleaning liquid supply unit.

5. The substrate processing apparatus of claim 4,
wherein the cleaning processing unit further comprises a rinse liquid supply unit configured to supply a rinse liquid onto the substrate, and
the control unit controls the first cleaning liquid supply unit, the second cleaning liquid supply unit, the third cleaning liquid supply unit and the rinse liquid supply unit such that the rinse liquid is supplied onto the substrate from the rinse liquid supply unit after the first cleaning liquid is supplied by the first cleaning liquid supply unit and before the second cleaning liquid is supplied by the second cleaning liquid supply unit, and/or after the second cleaning liquid is supplied by the second cleaning liquid supply unit and before the third cleaning liquid is supplied by the third cleaning liquid supply unit.

6. The substrate processing apparatus of claim 1, further comprising:
a coating processing unit configured to perform a coating process of coating the copper wiring of the substrate with a metal film,
wherein the control unit controls the cleaning processing unit and the coating processing unit such that the coating process is performed on the substrate by the coating processing unit after performing the cleaning process by the cleaning processing unit.

7. The substrate processing apparatus of claim 6, further comprising:
a hydrophobizing agent solution supply unit configured to supply a hydrophobizing agent solution onto the substrate,
wherein the control unit controls the cleaning processing unit, the coating processing unit and the hydrophobizing agent solution supply unit such that the hydrophobizing agent solution is supplied onto the substrate by the hydrophobizing agent solution supply unit after performing the cleaning process by the cleaning processing unit and before performing the coating process by the coating processing unit.

8. The substrate processing apparatus of claim 6,
wherein the coating process is an electroless plating process.

9. A substrate processing method including a cleaning process of removing, from a substrate having a copper wiring formed by a dry etching process using an organic etching gas, an organic polymer which is originated from the organic etching gas and generated in the dry etching process and adheres to a surface of the substrate,
wherein, in the cleaning process, a first cleaning liquid selected from a chemical liquid containing hydrogen peroxide and a chemical liquid containing a polar organic solvent is supplied onto the substrate.

10. The substrate processing method of claim 9,
wherein the organic etching gas is one or more kinds of gases selected from a methane gas, a CF-based gas, a carboxylic acid-based gas containing a methyl group and an alcohol-based gas.

11. The substrate processing method of claim 9,
wherein, in the cleaning process, a second cleaning liquid selected from an aqueous solution containing hydrogen fluoride and a strong alkaline aqueous solution is supplied onto the substrate after the first cleaning liquid is supplied.

12. The substrate processing method of claim 11,
wherein, in the cleaning process, a third cleaning liquid, which is selected from an aqueous solution containing hydrogen fluoride and a strong alkaline aqueous solution and is different from the second cleaning liquid, is supplied onto the substrate after the second cleaning liquid is supplied.

13. The substrate processing method of claim 12,
wherein, in the cleaning process, a rinse liquid is supplied onto the substrate after the first cleaning liquid is supplied and before the second cleaning liquid is supplied, and/or after the second cleaning liquid is supplied and before the third cleaning liquid is supplied.

14. The substrate processing method of claim 9, further comprising:
a coating process of coating the copper wiring of the substrate with a metal film after the cleaning process.

15. The substrate processing method of claim 14, further comprising:
a hydrophobizing agent solution supplying process of supplying a hydrophobizing agent solution onto the substrate after the cleaning process and before the coating process.

16. The substrate processing method of claim 14,
wherein, in the coating process, the copper wiring of the substrate is coated with the metal film by an electroless plating process.

17. A substrate processing method, comprising:
preparing a substrate having a copper wiring provided with a preset wiring pattern by a dry etching process;
removing an organic polymer, which is originated from an etching gas and generated in the dry etching process and adheres to a surface of the copper wiring, with a cleaning liquid; and
coating the surface of the copper wiring of the substrate selectively with a metal film after the removing of the organic polymer.

18. A computer-readable recording medium having stored thereon computer-executable instructions that, in response to execution, cause a substrate processing apparatus to perform a substrate processing method as claimed in claim 9.
